(19) United States
(12) Patent Application Publication
(10) Pub. No.: US 2026/0033102 A1
(43) Pub. Date: Jan. 29, 2026

(54) DISPLAY APPARATUS, ELECTRONIC DEVICE INCLUDING THE DISPLAY APPARATUS, AND METHOD OF MANUFACTURING THE DISPLAY APPARATUS

(71) Applicant: Samsung Display Co., Ltd., Yongin-si (KR)

(72) Inventors: Sangduk Lee, Yongin-si (KR); Hoikwan Lee, Yongin-si (KR); Sungwon Kim, Yongin-si (KR); Junyeub Lee, Yongin-si (KR)

(21) Appl. No.: 19/212,908

(22) Filed: May 20, 2025

(30) Foreign Application Priority Data
Jul. 23, 2024 (KR) 10-2024-0097504

(51) Int. Cl. H10H 29/855; H10H 29/01

(52) U.S. Cl. CPC H10H 29/855; H10H 29/012; H10H 29/0363

(57) ABSTRACT

Provided is a display apparatus including a display panel including a plurality of light-emitting diodes disposed on a substrate, and a window disposed on the display panel and covering the display panel, wherein the window includes a first portion having a first refractive index, and a second portion having a second refractive index different from the first refractive index, and in a plan view, the first portion and the second portion are disposed alternately with each other.

This application claims priority to Korean Patent Application No. 10-2024-0097504, filed on Jul. 23, 2024, and all the benefits accruing therefrom under 35 U.S.C. § 119, the content of which in its entirety is herein incorporated by reference.

### BACKGROUND

### 1. Field

One or more embodiments relate to a display apparatus, and more particularly, to a display apparatus including a light-emitting diode. One or more embodiments relate to a method of manufacturing a display apparatus including a light-emitting diode. One or more embodiments relate to an electronic device including a display apparatus.

### 2. Description of the Related Art

An electronic device may include display apparatuses visually displaying data. Display apparatuses may provide images by using light-emitting diodes. The use of display apparatuses has diversified, and various designs have been attempted to improve the quality of display apparatuses.

A display apparatus may include a display panel that includes a plurality of light-emitting diodes as display elements. The display apparatus may also include a window (or cover window) on the display panel to protect elements of the display panel. In some cases, the window may be treated to reduce reflection of external light.

### SUMMARY

Other treatments as described above may include a process of sequentially disposing a film with a high refractive index (hereinafter, “high refractive index film”) and a film with a low refractive index (hereinafter, “low refractive index film) on glass. External light passing through a high refractive index film and reflected from a glass surface and external light passing through a low refractive index film and reflected from a glass surface may cause destructive interference with each other. Accordingly, the overall reflectivity of the window may be reduced. However, this technique requires an additional film be disposed on the glass. Disposing an additional film on the glass has a problem of increasing a thickness of the window and requiring additional processes.

Additional aspects will be set forth in part in the description which follows and, in part, will be apparent from the description, or may be learned by practice of the presented embodiments of the disclosure.

According to one or more embodiments, a display apparatus including a display panel including a plurality of light-emitting diodes disposed on a substrate, and a window disposed on the display panel and covering the display panel, wherein the window includes a first portion having a first refractive index, and a second portion having a second refractive index different from the first refractive index, and in a plan view, the first portion and the second portion are disposed alternately with each other.

In an embodiment, the first portion and the second portion may be disposed alternately with each other in a direction perpendicular to a thickness direction of the window.

In an embodiment, the first portion may have a relatively negative charge and the second portion may have a relatively positive charge.

In an embodiment, the first refractive index may be less than the second refractive index.

In an embodiment, a thickness of the first portion in a thickness direction of the window may be less than a thickness of the window.

In an embodiment, the first portion and the second portion may be disposed on an upper surface of the window.

According to one or more embodiments, an electronic device includes a display apparatus including a display panel including a plurality of light-emitting diodes disposed on a substrate, and a window disposed on the display panel and covering the display panel, wherein the window includes, on an upper surface of the window, a first zone having a first refractive index and a second zone having a second refractive index different from the first refractive index, wherein the first zone and the second zone are disposed alternately with each other in a direction perpendicular to a thickness direction of the window.

In an embodiment, the first refractive index of the first zone may be less than the second refractive index of the second zone.

In an embodiment, the first zone may have a relatively negative charge compared to the second zone.

In an embodiment, the upper surface has undergone thermal poling treatment.

In an embodiment, the thermal poling treatment may include a treatment of bringing an electrode into contact with the first zone of the upper surface of the window and applying a voltage to the electrode.

In an embodiment, a lower surface of the window facing the display panel may have a constant refractive index in the direction perpendicular to the thickness direction of the window.

According to one or more embodiments, a method of manufacturing a display apparatus includes bringing an electrode having a protrusion into contact with a first surface of a window, performing thermal poling treatment on the window by applying a voltage to the window through the electrode, and attaching the window on which the thermal poling treatment has been performed onto a display panel including a plurality of light-emitting diodes.

In an embodiment, the method may further include disposing the window between an anode and a cathode.

In an embodiment, the electrode may be disposed between the first surface of the window and the anode.

In an embodiment, the cathode may be in direct contact with a second surface of the window, the second surface being opposite to the first surface of the window.

In an embodiment, the protrusion of the electrode may be in contact with a first zone of the first surface of the window.

In an embodiment, the performing of the thermal poling treatment may include moving a positive charge positioned in the first zone to a second zone adjacent to the first zone by applying a positive voltage to the first zone.

In an embodiment, the performing of the thermal poling treatment may be at a temperature of 200° C. or more.

In an embodiment, in the attaching of the window onto the display panel, the first surface of the window may face in a direction away from the display panel.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view schematically illustrating a display apparatus according to an embodiment;

FIG. 2 is a cross-sectional view schematically illustrating a display apparatus according to an embodiment;

FIG. 3 is a cross-sectional view of part of a display panel according to an embodiment;

FIG. 4 is a cross-sectional view schematically illustrating a window according to an embodiment;

FIG. 5 is a plan view schematically illustrating a window according to an embodiment;

FIG. 6 is a plan view schematically illustrating a window according to an embodiment;

FIG. 7 is a plan view schematically illustrating a window according to an embodiment; and

FIGS. 8A, 8B, 8C, and 8D are cross-sectional views schematically illustrating operations of a method of manufacturing a display apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are described herein, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in detail. Hereinafter, effects and features of the disclosure and a method for accomplishing them will be described with reference to the accompanying drawings, in which embodiments of the disclosure are illustrated. This disclosure may, however, be embodied in many different forms and should not be construed as limited to the embodiments set forth herein.

Hereinafter, when describing with reference to drawings, identical or corresponding elements are given the same drawing reference numerals and redundant descriptions thereof are omitted.

While such terms as “first” and “second” may be used to describe various elements, such elements are not to be limited to the above terms. The above terms are used to distinguish one element from another element.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of description. For example, sizes and thicknesses of elements in the drawings are arbitrarily illustrated for convenience of explanation, and the disclosure is not limited thereto.

When an embodiment may be implemented differently, a certain process order may be performed differently from the described order. For example, two consecutively described processes may be performed substantially at the same time or performed in an order opposite to the described order.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within +30%, 20%, 10%, 5% of the stated value, for example.

The term “substantially,” as used herein, means approximately or actually. The term “substantially simultaneously” means approximately or actually simultaneously. The term “substantially at the same time” means approximately or actually at the same time.

Herein, “A and/or B” means A or B, or A and B. In some aspects, “at least one of A and B” represents the case of A, B, or A and B.

It will be understood that when a layer, region, or element is referred to as being “connected” to another layer, region, or element, it may be “directly connected” to the other layer, region, or element or/and may be “indirectly connected” to the other layer, region, or element with other layer, region, or element therebetween. For example, it will be understood that when a layer, region, or element is referred to as being “electrically connected” to another layer, region, or element, it may be “directly electrically connected” to the other layer, region, or element and/or may be “indirectly electrically connected” to other layer, region, or element with other layer, region, or element therebetween.

x, y, and z are not limited to the three directions on the orthogonal coordinate system, and can be interpreted in a broad sense that includes them. For example, x, y, and z may be perpendicular to one another, or may represent different directions that are not perpendicular to one another.

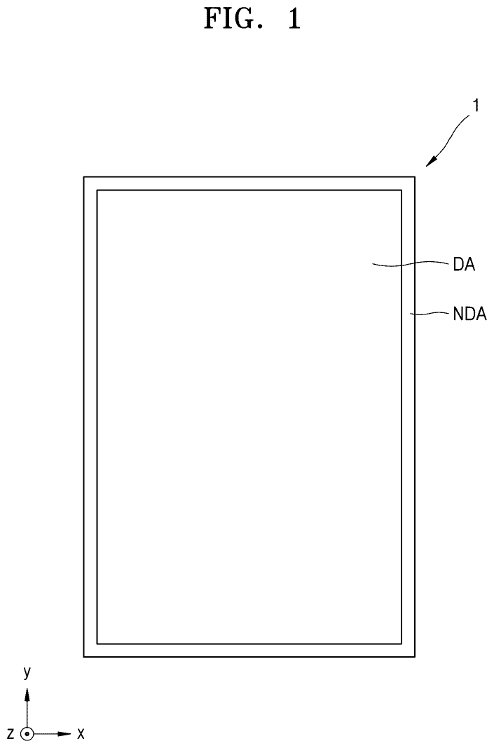

FIG. 1 is a plan view schematically illustrating a display apparatus 1 according to an embodiment.

Referring to FIG. 1, the display apparatus 1 may include a display area DA and a non-display area NDA. Sub-pixels having light-emitting diodes may be disposed in the display area DA and provide a certain image. The non-display area NDA, in which no image is provided, may surround the display area DA. Scan drivers and data drivers configured to provide electrical signals to be applied to the sub-pixels of the display area DA and power lines configured to provide power such as, for example, driving voltage and common voltage may be disposed in the non-display area NDA.

In FIG. 1, a length of the display apparatus 1 in an x-direction is less than a length of the display apparatus 1 in a y-direction. However, one or more embodiments are not limited thereto. In another embodiment, the length in the x-direction may be greater than the length in the y-direction, and a shape of the display apparatus 1 may vary.

The display apparatus 1 may be applicable to or integrated with various electronic devices such as, for example, mobile phones, smartphones, tablet personal computers (PCs), mobile communication terminals, electronic notebooks, electronic books, portable multimedia players (PMPs), navigations, ultra mobile PCs (UMPCs), televisions, laptops, monitors, billboards, and Internet of things (IoT). In some aspects, the display apparatus 1 according to an embodiment may be applicable to or integrated with wearable electronic devices such as, for example, smart watches, watch phones, glasses-type displays, and head-mounted displays (HMDs). In some aspects, the display apparatus 1 according to an embodiment may be applicable to or integrated with electronic devices of a vehicle such as, for example an instrument panel of a vehicle, a center information display (CID) disposed on a center fascia or dashboard, a mirror display replacing a side-view mirror of a vehicle, and a display screen disposed on the rear surface of a front seat as an entertainment of a vehicle.

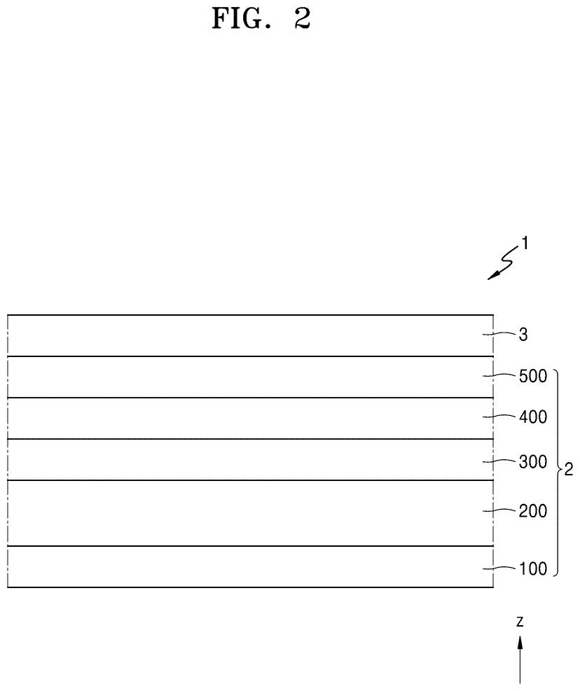

FIG. 2 is a cross-sectional view schematically illustrating the display apparatus 1 according to an embodiment.

Referring to FIG. 2, the display apparatus 1 may include a display panel 2 and a window 3. The window 3 may be disposed on the display panel 2. The window 3 may entirely cover the display panel 2.

The display panel 2 may include a substrate 100, a display layer 200, an encapsulation layer 300, a touch layer 400, and an optical layer 500. The display panel 2 may be disposed on the substrate 100, and may include a plurality of light-emitting diodes disposed within the display layer 200 as a display element.

The substrate 100 may include glass or polymer resin. In an embodiment, the polymer resin may include polyethersulfone, polyacrylate, polyetherimide, polyethylene naphthalate, polyethylene terephthalate, polyphenylene sulfide, polyarylate, polyimide, polycarbonate, cellulose acetate propionate, and the like. The substrate 100 including the polymer resin may have flexible, rollable, or bendable properties. The substrate 100 may have a single-layer structure or multi-layer structure. In an example in which the substrate 100 has a multi-layer structure, the substrate 100 may include a layer including polymer resin and a layer including an inorganic insulating material.

The display layer 200 may be disposed on the substrate 100. The display layer 200 may include a light-emitting diode as a display element, a thin-film transistor electrically connected to the light-emitting diode, and insulating layers between the light-emitting diode and the thin-film transistor.

The encapsulation layer 300 may be disposed on the display layer 200. Alternatively, the display layer 200 may be covered and sealed by the encapsulation layer 300. The encapsulation layer 300 may include at least one inorganic encapsulation layer and at least one organic encapsulation layer.

In an embodiment, the display apparatus 1 may have an encapsulation substrate (not illustrated) formed of glass instead of the encapsulation layer 300. The encapsulation substrate may be disposed on the display layer 200, and the display layer 200 may be between the substrate 100 and the encapsulation substrate. A gap may be between the encapsulation substrate and the display layer 200, and this gap may be filled with a filler.

The touch layer 400 may be disposed on the encapsulation layer 300. The touch layer 400 detects an external input, e.g., a touch of an object such as, for example, a finger or stylus pen, such that the display apparatus 1 may obtain coordinate information corresponding to a touch position. The touch layer 400 may include a touch electrode and trace lines connected to the touch electrode. The touch layer 400 may detect an external input by using a mutual cap method or self cap method.

In an embodiment, the touch layer 400 may be formed directly on the encapsulation layer 300. Alternatively, the touch layer 400 may be separately formed, and then may be adhered to the encapsulation layer 300 through an adhesive layer such as, for example, an optically clear adhesive (OCA).

The optical layer 500 may be disposed on the touch layer 400. The optical layer 500 may include a light-shielding layer and/or a color filter. The color filter may have a color corresponding to light emitted from an emission element disposed under each color filter.

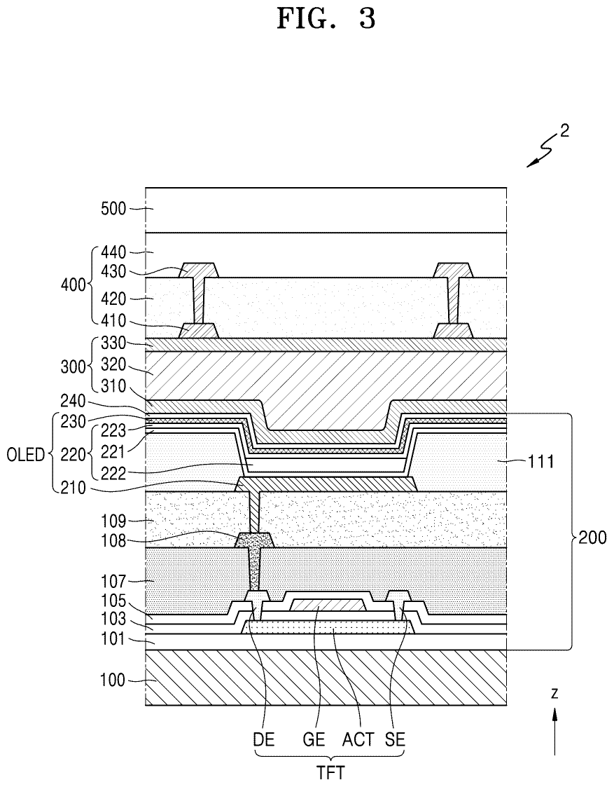

FIG. 3 is a cross-sectional view of part of the display panel 2 according to an embodiment. For example, FIG. 3 may be a cross-sectional view illustrating part of the display panel 2 taken from the display area DA.

Referring to FIG. 3, a light-emitting diode LED may be disposed on the substrate 100 as a display element. The light-emitting diode LED may be electrically connected to a thin-film transistor TFT.

The display layer 200 may be disposed on the substrate 100. The display layer 200 may include a buffer layer 101, a gate insulating layer 103, an interlayer insulating layer 105, the thin-film transistor TFT, a first organic insulating layer 107, a contact metal 108, a second organic insulating layer 109, a pixel-defining layer 111, the light-emitting diode LED, and a capping layer 240.

The buffer layer 101 may be disposed on the substrate 100. The buffer layer 101 may serve to planarize and protect an upper surface of the substrate 100. The buffer layer 101 may include at least one inorganic insulating material from among silicon oxide (SiOₓ), silicon nitride (SiNₓ), and/or silicon oxynitride (SiON). The buffer layer 101 may have a single-layer structure or multi-layer structure.

The thin-film transistor TFT may be disposed on the buffer layer 101. The thin-film transistor TFT may include an active layer ACT, a gate electrode GE, a source electrode SE, and a drain electrode DE. The thin-film transistor TFT may be connected to the light-emitting diode LED and may drive the light-emitting diode LED.

The active layer ACT may be disposed on the buffer layer 101, and may include a drain region overlapping the drain electrode DE, a source region overlapping the source electrode SE, and a channel region disposed between the drain region and the source region. The drain region and the source region may be doped with impurities (i.e., dopants).

The gate insulating layer 103 may be disposed on the active layer ACT. The gate insulating layer 103 may include an inorganic insulating material. For example, the gate insulating layer 103 may include at least one inorganic insulating material, such as, for example, silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The gate insulating layer 103 may have a single-layer structure or multi-layer structure.

The gate electrode GE may be disposed on the gate insulating layer 103. The gate electrode GE may overlap the active layer ACT. For example, the gate electrode GE may overlap the channel region of the active layer ACT. The gate electrode GE may include at least one conductive material from among aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu). The gate electrode GE may have a single-layer structure or multi-layer structure.

The interlayer insulating layer 105 may be disposed on the gate electrode GE. The interlayer insulating layer 105 may include an inorganic insulating material. For example, the interlayer insulating layer 105 may include at least one inorganic insulating material, such as, for example, SiOₓ, SiNₓ, SiON, Al₂O₃, TiO₂, Ta₂O₅, HfO₂, or ZnO₂. The interlayer insulating layer 105 may have a single-layer structure or multi-layer structure.

The gate insulating layer 103 and the interlayer insulating layer 105 may include a contact hole overlapping the source region of the active layer ACT and a contact hole overlapping the drain region of the active layer ACT. The source electrode SE and the drain electrode DE may be disposed on the interlayer insulating layer 105. The source electrode SE may be disposed to overlap the source region of the active layer ACT, and the drain electrode DE may be disposed to overlap the drain region of the active layer ACT. The source electrode SE and the drain electrode DE may be connected to the active layer ACT through contact holes defined in the gate insulating layer 103 and the interlayer insulating layer 105, respectively. For example, the source electrode SE may be connected to the source region of the active layer ACT, and the drain electrode DE may be connected to the drain region of the active layer ACT.

The first organic insulating layer 107 and the second organic insulating layer 109 may be sequentially disposed on the interlayer insulating layer 105. Each of the first organic insulating layer 107 and the second organic insulating layer 109 may include an opening overlapping the drain electrode DE. The contact metal 108 may be disposed on the first organic insulating layer 107. The contact metal 108 may be connected to the drain electrode DE through the opening defined in the first organic insulating layer 107. The opening defined in the second organic insulating layer 109 overlapping the drain electrode DE may overlap the contact metal 108.

The contact metal 108 may include Al, Cu, and/or Ti. The contact metal 108 may have a single-layer structure or multi-layer structure.

The first organic insulating layer 107 and the second organic insulating layer 109 may include general-purpose polymers, such as, for example, benzocyclobutene, polyimide, hexamethyldisiloxane, poly(methyl methacrylate), or polystyrene, polymer derivatives having a phenol-based group, acryl-based polymers, imide-based polymers, aryl ether-based polymers, amide-based polymers, fluorine-based polymers, p-xylene-based polymers, or vinyl alcohol-based polymers. Each of the first organic insulating layer 107 and the second organic insulating layer 109 may have a single-layer structure or multi-layer structure.

A pixel electrode 210 may be disposed on the second organic insulating layer 109. The pixel electrode 210 may be connected to the contact metal 108 through the opening defined in the second organic insulating layer 109. Accordingly, the pixel electrode 210 may be connected to the thin-film transistor TFT through the contact metal 108 and the drain electrode DE and may receive voltage.

The pixel electrode 210 may include a conductive oxide such as, for example, indium tin oxide (ITO), indium zinc oxide (IZO), zinc oxide (ZnO), indium oxide (In₂O₃), indium gallium oxide (IGO), or aluminum zinc oxide (AZO). The pixel electrode 210 may include a reflective film including Ag, Mg, Al, Pt, Pd, Au, NI, Nd, Ir, Cr, or a compound thereof. However, a configuration and material of the pixel electrode 210 are not limited thereto, and may be variously modified.

The pixel-defining layer 111 [may be disposed on the second organic insulating layer 109. The pixel-defining layer 111 may cover an edge of the pixel electrode 210. In other words, the pixel-defining layer 111 may be opened to expose a central portion of the pixel electrode 210. A size and shape of an emission area of the light-emitting diode LED may be determined by the opening defined in the pixel-defining layer 111.

An intermediate layer 220 may be disposed on the pixel electrode 210. The intermediate layer 220 may include a first common layer 221 and a second common layer 223 disposed on the pixel-defining layer 111, and an emission layer 222 disposed in the opening defined in the pixel-defining layer 111. In an embodiment, the first common layer 221 may be disposed on the pixel-defining layer 111, and the emission layer 222 may be disposed in the opening defined in the pixel-defining layer 111 on the first common layer 221, and the second common layer 223 may be disposed on the first common layer 221 and cover the emission layer 222. In other words, the emission layer 222 may be disposed in the opening defined in the pixel-defining layer 111, and may be between the first common layer 221 and the second common layer 223.

The emission layer 222 may include an organic emission layer including a low-molecular weight or polymer material. The first common layer 221 may include an electron transport layer (ETL) and/or an electron injection layer (EIL). The second common layer 223 may include a hole transport layer (HTL) and/or a hole injection layer (HIL). In an embodiment, the first common layer 221 or the second common layer 223 may be omitted. In an embodiment, the first common layer 221 and the second common layer 223 may be swapped.

An opposite electrode 230 may be disposed on the intermediate layer 220. For example, the opposite electrode 230 may be disposed on the second common layer 223. The opposite electrode 230 may entirely cover the intermediate layer 220. The opposite electrode 230 may include a conductive material with a low work function. For example, the opposite electrode 230 may include a (semi-) transparent layer including Ag, Mg, Al, Pt, Pd, Au, Ni, Nd, Ir, Cr, Li, CA, or an alloy thereof. Alternatively, the opposite electrode 230 may further include a layer including ITO, IZO, ZnO, or In₂O₃, on the (semi-) transparent layer including the materials described herein.

The capping layer 240 may be disposed on the opposite electrode 230. The capping layer 240 may have a refractive index that is lower than a refractive index of the opposite electrode 230, and may reduce a proportion of light generated in the intermediate layer 220 that is not emitted to the outside due to total reflection, thereby improving light efficiency.

The capping layer 240 may be an organic capping layer including an organic material, an inorganic capping layer including an inorganic material, and a composite capping layer including an organic material and an inorganic material. For example, the capping layer 240 may include a carbocyclic compound, a heterocyclic compound, an amine group-containing compound, porphine derivatives, phthalocyanine derivatives, naphthalocyanine derivatives, an alkaline metal complex, an alkaline earth metal complex, or a combination thereof. Alternatively, the capping layer 240 may include an inorganic material such as, for example, zinc oxide (ZnO), titanium oxide (TiOₓ), zirconium oxide (ZrOₓ), nitrogen oxide (NO), niobium oxide (NbOₓ), tantalum oxide (TaOₓ), tin oxide (SnOₓ), nickel oxide (NiOₓ), indium nitride (InN), or gallium nitride (GaN). However, a material that may be included in the capping layer 240 is not limited thereto, and the capping layer 240 may be formed of various materials.

The encapsulation layer 300 may be disposed on the capping layer 240. The encapsulation layer 300 may include at least one inorganic layer and at least one organic layer. In an embodiment, the encapsulation layer 300 may include a first inorganic encapsulation layer 310, a second inorganic encapsulation layer 330, and an organic encapsulation layer 320 between the first inorganic encapsulation layer 310 and the second inorganic encapsulation layer 330. The first inorganic encapsulation layer 310 and/or the second inorganic encapsulation layer 330 may include one or more inorganic insulating materials such as, for example, SiOₓ, SiNₓ, SiON, Al₂O₃, TiO₂, Ta₂O₅, HfO₂, or ZnO₂. The organic encapsulation layer 320 may include a polymer-based material. The polymer-based material may include silicon-based resin, acryl-based resin, epoxy-based resin, polyimide, and polyethylene.

The touch layer 400 may be disposed on the encapsulation layer 300. The touch layer 400 may include a first touch electrode 410, a first touch insulating layer 420, a second touch electrode 430, and a second touch insulating layer 440. The first touch electrode 410 may be disposed on the encapsulation layer 300. For example, the first touch electrode 410 may be disposed on the second inorganic encapsulation layer 330. The first touch insulating layer 420, the second touch electrode 430, and the second touch insulating layer 440 may be sequentially disposed on the first touch electrode 410. The first touch insulating layer 420 and/or the second touch insulating layer 440 may include an inorganic insulating material and/or an organic insulating material. The first touch electrode 410 and the second touch electrode 430 may not overlap an emission area of the light-emitting diode LED. For example, the first touch electrode 410 and the second touch electrode 430 may not overlap the pixel electrode 210 or the opening defined in the pixel-defining layer 111.

In some embodiments, an insulating film may be further disposed between the first touch electrode 410 and the second inorganic encapsulation layer 330. The insulating film may include at least one inorganic insulating material selected from among SiOₓ, SiNₓ, and SiON.

The optical layer 500 may be disposed on the touch layer 400. For example, the optical layer 500 may be disposed on the second touch insulating layer 440. The optical layer 500 may include a light-shielding layer (not illustrated) and/or a color filter (not illustrated).

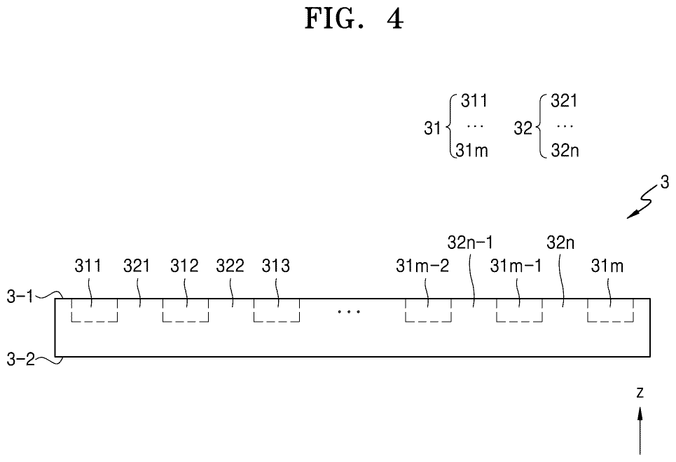

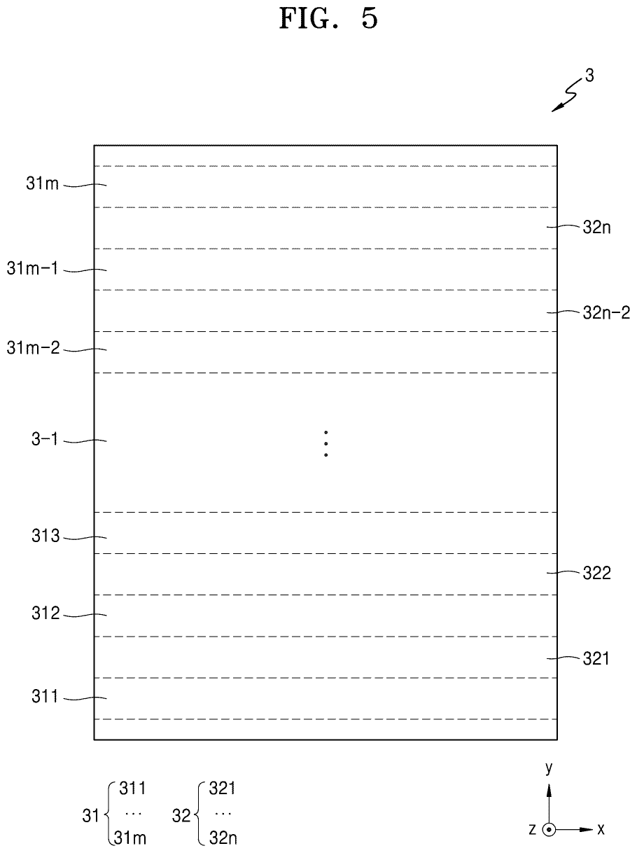

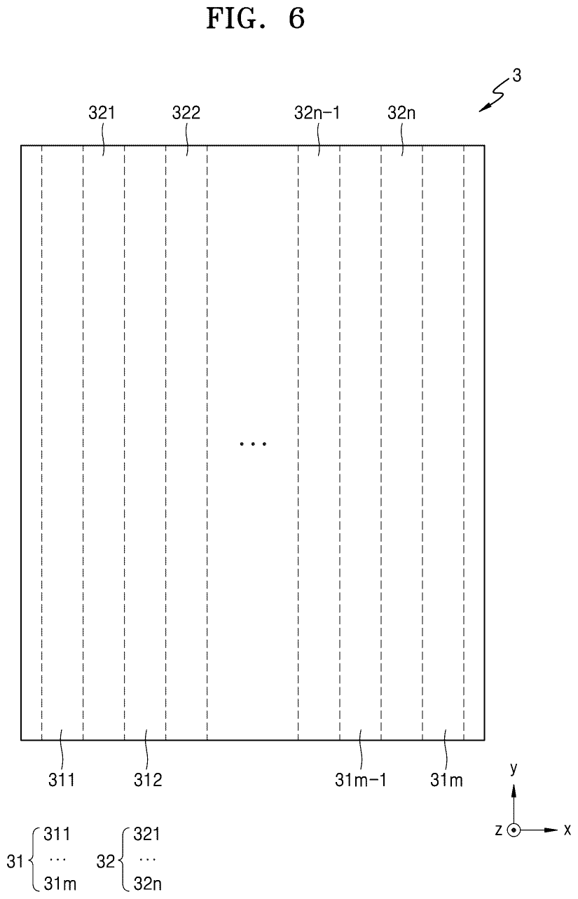

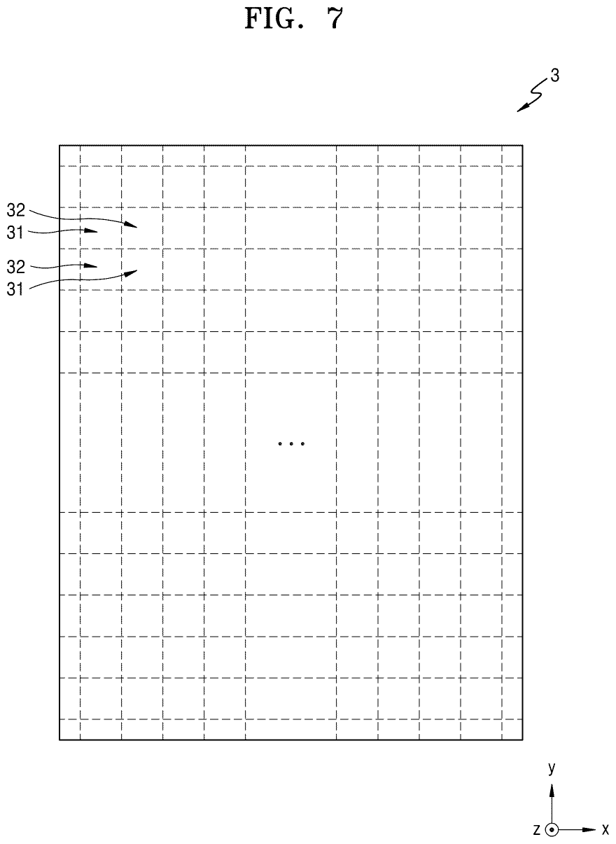

FIG. 4 is a cross-sectional view schematically illustrating the window 3 according to an embodiment. FIG. 5 is a plan view schematically illustrating the window 3 according to an embodiment. FIG. 6 is a plan view schematically illustrating the window 3 according to another embodiment. FIG. 7 is a plan view schematically illustrating the window 3 according to another embodiment.

Herein, the window 3 may include a cover glass or may be the cover glass itself. Hereinbelow, it is illustrated and described in detail that the cover glass is the window 3 itself. Accordingly, hereinbelow, it may be understood that the window 3 refers to the cover glass.

The window 3 may include a first surface 3-1 and a second surface 3-2. In an embodiment, the first surface 3-1 of the window 3 may be an upper surface of the window 3. In an embodiment, the second surface 3-2 of the window 3 may be a lower surface of the window 3. In an embodiment, the second surface 3-2 of the window 3 may be a surface facing the display panel 2 (see FIG. 2) described herein.

The window 3 may include a first portion 31 and a second portion 32. In an embodiment, the first portion 31 may be a first zone. In an embodiment, the second portion 32 may be a second zone. In an embodiment, the first portion 31 and the second portion 32 of the window 3 may be formed on the first surface 3-1 of the window 3. In other words, the first portion 31 (or the first zone) and the second portion 32 (or the second zone) may be formed on an upper surface of the window 3.

The first portion 31 and the second portion 32 may be disposed alternately in one direction. For example, the first portion 31 and the second portion 32 may be disposed alternately in a direction perpendicular to a thickness direction (e.g., a z-axis direction) of the window 3. The first portion 31 may include a first-1 subportion 311 to a first-m subportion 31m. In an embodiment, the first-1 subportion 311 to the first-m subportion 31m may be a first-1 subzone to a first-n subzone, respectively. The second portion 32 may include a second-1 subportion 321 to a second-n subportion 32n. In an embodiment, the second-1 subportion 321 to the second-n subportion 32n may be a second-1 subzone to a second-n subzone, respectively. In an embodiment, m and n may be identical to each other. In another embodiment, m and n may be different from each other.

The first-1 subportion 311 to the first-m subportion 31m may be disposed alternately in the one direction (e.g., the direction perpendicular to the thickness direction of the window 3) with the second-1 subportion 321 to the second-n subportion 32n.

In an embodiment, referring to FIG. 5, each of the first portion 31 and the second portion 32 may include subportions extending in the x-axis direction. The first-1 subportion 311 to the first-m subportion 31m and the second-1 subportion 321 to the second-n subportion 32n may extend in the x-axis direction. The subportions of the first portion 31 and subportions of the second portion 32 may be disposed alternately in the y-axis direction. The first-1 subportion 311 to the first-m subportion 31m and the second-1 subportion 321 to the second-n subportion 32n may be disposed alternately in the y-axis direction. For example, the first-1 subportion 311, the second-1 subportion 321, a first-2 subportion 312, a second-2 subportion 322, and a first-3 subportion 313 may be sequentially disposed in the y-axis direction.

In another embodiment, referring to FIG. 6, each of the first portion 31 and the second portion 32 may include subportions extending along the y-axis. The first-1 subportion 311 to the first-m subportion 31m and the second-1 subportion 321 to the second-n subportion 32n may extend in the y-axis direction. The subportions of the first portion 31 and subportions of the second portion 32 may be disposed alternately in the x-axis direction. The first-1 subportion 311 to the first-m subportion 31m and the second-1 subportion 321 to the second-n subportion 32n may be disposed alternately in the x-axis direction. For example, the first-1 subportion 311, the second-1 subportion 321, the first-2 subportion 312, the second-2 subportion 322, and the first-3 subportion 313 may be sequentially disposed in the x-axis direction.

In another embodiment, referring to FIG. 7, the first portion 31 and the second portion 32 may be disposed in a grid shape. The subportions of the first portion 31 and subportions of the second portion 32 may be disposed in a grid shape (or checkered pattern). The subportions of the first portion 31 may be spaced apart from each other by the subportions of the second portion 32. The subportions of the second portion 32 may be spaced apart from each other by the subportions of the first portion 31.

However, one or more embodiments are not limited to these planar shapes and may include embodiments illustrating various arrangements of the first portion 31 and the second portion 32 of the window 3.

The window 3 may have a first refractive index in the first portion 31. The window 3 may have a second refractive index in the second portion 32. In an embodiment, the first refractive index and the second refractive index may be different from each other. In an embodiment, the first refractive index may be less than the second refractive index. In an embodiment, the first refractive index may be greater than the second refractive index.

Accordingly, when viewed from the upper surface (i.e., first surface 3-1) side of the window 3, the window 3 may include a structure in which portions (or zones) with different refractive indices are disposed alternately in one direction (e.g., x-axis direction and/or y-axis direction).

The window 3 may have a first charge in the first portion 31. The window 3 may have a second charge in the second portion 32. In an embodiment, the first charge may be relatively negative compared to the second charge. In this case, the first portion 31 of the window 3 may have a relatively negative charge compared to the second portion 32. In other words, the second portion 32 of the window 3 may have a relatively positive charge compared to the first portion 31. In an embodiment, the first charge may be relatively positive compared to the second charge. In this case, the first portion 31 of the window 3 may have a relatively positive charge compared to the second portion 32. In other words, the second portion 32 of the window 3 may have a relatively negative charge compared to the first portion 31.

Referring to FIG. 4 again, the first portion 31 may be partially formed in the window 3 in the thickness direction (e.g., z direction) of the window 3. In other words, a thickness of the first portion 31 in the thickness direction (e.g., z-axis direction) of the window 3 may be less than a thickness of the window 3 itself. In an embodiment, the second portion 32 may be entirely formed in the window 3 in the thickness direction (e.g., z direction) of the window 3. Accordingly, as illustrated in FIG. 4, a relationship between the first portion 31 and the second portion 32 is such that an opening is formed in the window 3, the first portion 31 fills the opening, and the remaining portion excluding the opening corresponds to the second portion 32. However, this is a description to help understanding, and one or more embodiments do not assume that an opening is formed in the window 3.

Accordingly, when viewed from a lower surface (i.e., second surface 3-2) of the window 3, the window 3 may include a structure having a constant refractive index, e.g., a second refractive index.

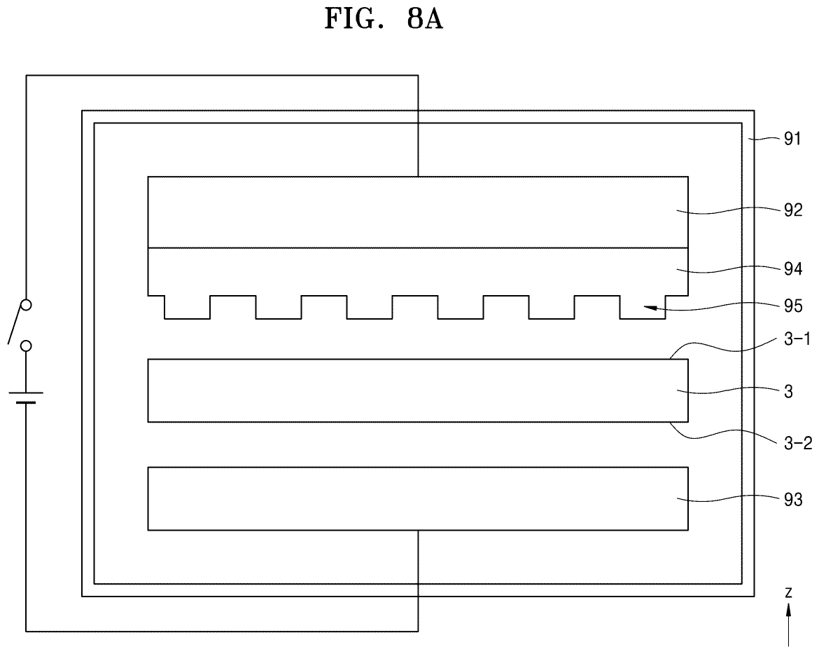

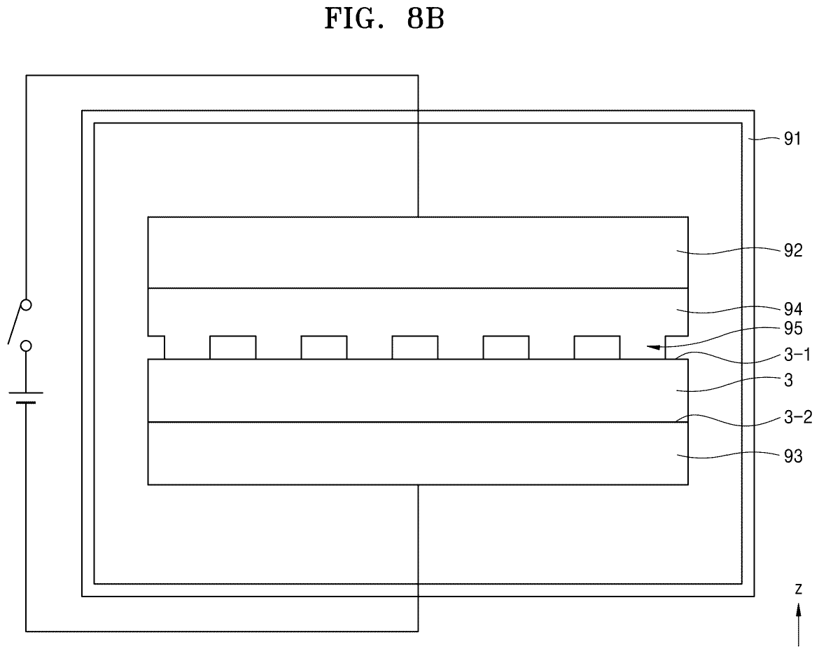

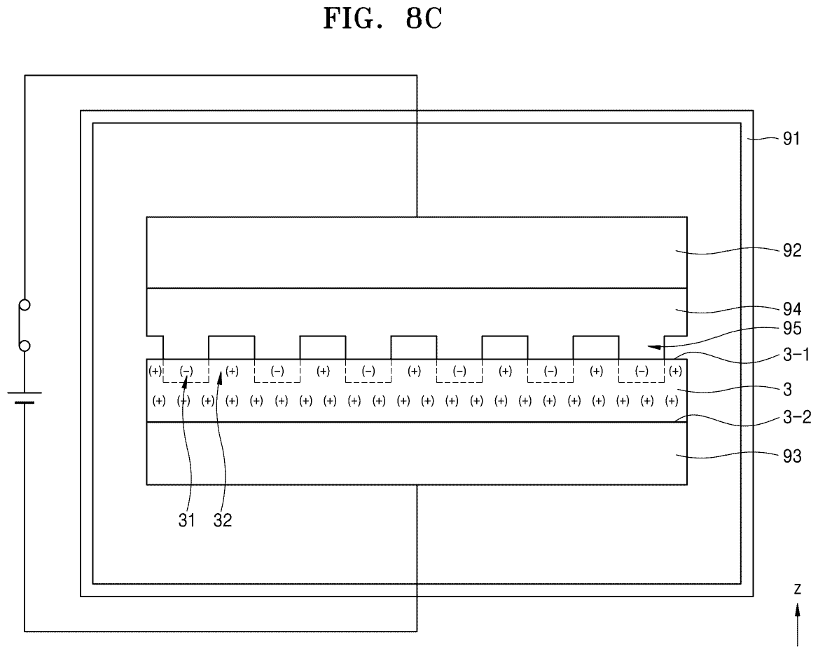

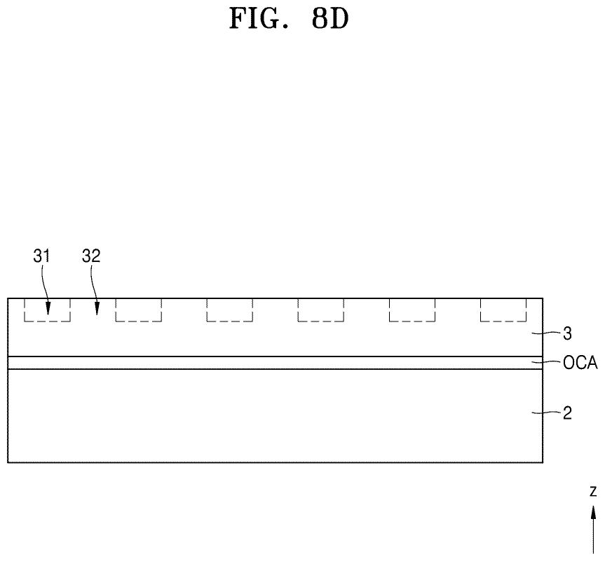

In an embodiment, the upper surface (i.e., first surface 3-1) of the window 3 may be subjected to thermal poling treatment described herein. The thermal poling treatment may include, as described herein, a treatment of applying voltage after bringing an electrode into contact with the first portion 31 (or the first zone) on the upper surface (i.e., first surface 3-1) of the window 3. The thermal poling treatment is described herein in detail with reference to FIGS. 8A to 8D.

FIGS. 8A to 8D are cross-sectional views schematically illustrating operations of a method of manufacturing a display apparatus, according to an embodiment.

In the descriptions of the method and processes herein, the operations may be performed in a different order than the order shown and/or described, or the operations may be performed in different orders or at different times. Certain operations may also be left out, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 8A, the method may include disposing an anode 92, a cathode 93, a contact electrode 94, and the window 3 within a chamber 91. The anode 92 and the cathode 93 may be connected to a power source.

The contact electrode 94 may be disposed under the anode 92. Alternatively, the anode 92 may be disposed on the contact electrode 94. The window 3 may be disposed under the contact electrode 94. Alternatively, the contact electrode 94 may be disposed on the window 3. The upper surface (i.e., first surface 3-1) of the window 3 may face the contact electrode 94. In other words, the contact electrode 94 may be disposed between the anode 92 and the window 3. For example, the contact electrode 94 may be disposed between the first surface 3-1 of the window 3 and the anode 92. The cathode 93 may be disposed under the window 3. Alternatively, the window 3 may be disposed on the cathode 93. The lower surface (i.e., second surface 3-2) of the window 3 may face the cathode 93.

The window 3 may be disposed between the anode 92 and the cathode 93. For example, the window 3 may be disposed between the contact electrode 94 and the cathode 93. In an embodiment, the method may include, while disposing the anode 92, the cathode 93, and the contact electrode 94 within the chamber 91, loading the window 3 from the outside of the chamber 91 into the chamber 91.

The anode 92 may be in contact with the contact electrode 94. In an embodiment, the anode 92 and the contact electrode 94 may be integrally formed as a single body.

The contact electrode 94 may have a protrusion 95. The protrusion 95 may include a plurality of protrusions toward one direction. Expressed another way, the contact electrode 94 may have a plurality of protrusions 95 which protrude in the same direction (e.g., negative Z-direction in FIG. 8A). In the present embodiment, the contact electrode 94 may be disposed such that the protrusion 95 faces the window 3. For example, the contact electrode 94 may be disposed such that the protrusion 95 faces the first surface 3-1 of the window 3.

Referring to FIG. 8B, the method may include bringing the contact electrode 94 into contact with the window 3. For example, the contact electrode 94 may be brought into contact with the first surface 3-1 of the window 3. In this case, the protrusion 95 of the contact electrode 94 may be in contact with the first surface 3-1 of the window 3. Substantially simultaneously with bringing the contact electrode 94 into contact with the window 3, the method may include bringing the cathode 93 into contact with the window 3. For example, the cathode 93 may be brought into contact with the second surface 3-2 of the window 3.

The method may include forming the first portion 31 (see FIG. 4) and the second portion 32 (see FIG. 4) before the process operations described with reference to FIGS. 8A and 8B.

Referring to FIG. 8C, the method may include applying a voltage to the anode 92 and the cathode 93. For example, the method may include applying a positive voltage to the anode 92 and applying a negative voltage to the cathode 93. As the positive voltage is applied to the anode 92, a positive voltage may also be applied to the contact electrode 94. Accordingly, a positive voltage may also be applied to the protrusion 95 of the contact electrode 94. In other words, a voltage may be applied to the window 3 through the contact electrode 94.

Charges randomly disposed within the window 3 may be aligned in a certain pattern. As a positive voltage is applied to the protrusion 95, positive charges (indicated by (+)) of the window 3 may move away from a zone (e.g., the first zone) where the protrusion 95 contacts the window 3. In other words, the positive charges may move from the zone (e.g., the first zone) where the protrusion 95 contacts the window 3 to an adjacent zone (e.g., the second zone). Accordingly, the zone (e.g., the first zone) where the protrusion 95 contacts the window 3 may have a relatively negative charge. To express this, in FIG. 8C, a (−) sign is indicated in the zone where the protrusion 95 contacts the window 3. As a result, positive charges and negative charges within the window 3 may be aligned by a voltage applied to the window 3 through the protrusion 95.

In the process described herein, the method may include maintaining a high temperature within the chamber 91 to maintain positions of the charges within the window 3 even after the voltage is removed. In an embodiment, the method may include maintaining the temperature within the chamber 91 to about 200° C. or more. In an embodiment, the method may include maintaining the temperature within the chamber 91 to a melting temperature of the window 3, which is about 1500° C. to about 1600° C.

A treatment of redisposing the charges within the window 3 through the process described herein to achieve polarity and applying heat during the process of forming polarity may be understood as thermal poling treatment. Through the thermal poling treatment performed in association with the method described herein, the polarity achieved by the redisposition of the charges within the window 3 may be maintained even after the voltage is removed.

In this case, a portion of the window 3 in contact with the protrusion 95 may be defined as the first portion 31 described herein. Alternatively, performing the thermal poling treatment may include contacting the protrusion 95 with a predetermined zone (e.g., the first zone), and a portion to which the voltage is applied via contact may be defined as the first portion 31. A portion of the window 3 not in contact with the protrusion 95 may be defined as the second portion 32 described herein. Alternatively, performing the thermal poling treatment may include contacting the protrusion 95 with the predetermined zone (e.g., the first zone), and at this time, a portion not in contact may be understood as the second portion 32.

In other words, the protrusion 95 may be in contact with the first zone, and charges (e.g., positive charges) present in the first zone may be moved to an adjacent second zone by applying voltage through the protrusion 95, thereby forming the first portion 31 and the second portion 32.

The characteristics of the window 3 after thermal poling treatment may be different from the characteristics before thermal poling treatment. The first portion 31 having a relatively negative charge may have a first refractive index, and the second portion 32 having a relatively positive charge may have a second refractive index. In the present embodiment, the first refractive index and the second refractive index may be different from each other. For example, the first refractive index may be less than the second refractive index. In other words, a plurality of zones with different refractive indices may be formed on the upper surface (i.e., first surface 3-1) of the window 3 through thermal poling treatment. In this case, the window 3 may have an overall constant refractive index (e.g., the second refractive index) in a portion adjacent to the second surface 3-2 where relatively positive charges are evenly distributed.

Referring to FIG. 8D, with reference to the window 3 on which thermal poling treatment is performed, the method may include removing the window 3 from the chamber 91 and attaching the window 3 onto the display panel 2. In this case, the upper surface of the window 3 on which the first portion 31 and the second portion 32 are formed may face in a direction away from the display panel 2. In other words, the window 3 may be attached onto the display panel 2 such that the first surface 3-1 (see FIG. 8C) of the window 3 faces in a direction away from the display panel 2. In other words, the window 3 may be attached onto the display panel 2 such that the lower surface (i.e., second surface 3-2 (see FIG. 8C)) of the window 3 faces the display panel 2. In an embodiment, the method may include disposing an OCA between the window 3 and the display panel 2.

It would be apparent to those skilled in the art that an embodiment in which the positions of the anode 92 and cathode 93 are swapped in the embodiments described herein also falls within the scope of the disclosure. In this case, a polarity (sign) of the voltage or a direction of current applied to the window 3 may be different from those of the one or more embodiments described herein. In this case, the characteristics of the first portion 31 and the second portion 32 of the window 3 may be different from those of the one or more embodiments described herein.

According to an embodiment configured as described herein, a display apparatus including a window in which surface treatment is performed on glass itself may be provided.

The glass of the window may include a structure in which a region (or portion) with a high refractive index and an area (or portion) with a low refractive index are disposed alternately. Reflected light of external light from each region (or portion) of the glass may cause destructive interference, which may reduce reflectivity of the entire window.

The window of the display apparatus according to the disclosure may be implemented without a separate film disposed on a surface of the glass. In an example, in accordance with one or more embodiments of the present disclosure, the window of the display apparatus according to the disclosure does not require a separate film be disposed on a surface of the glass. Therefore, a thickness of the window may be reduced, which may lead to a reduction in the thickness of the entire display apparatus.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel comprising a plurality of light-emitting diodes disposed on a substrate; and
a window disposed on the display panel and covering the display panel,
wherein the window comprises:
a first portion having a first refractive index; and
a second portion having a second refractive index different from the first refractive index, and
in a plan view, the first portion and the second portion are disposed alternately with each other.

2. The display apparatus of claim 1, wherein the first portion and the second portion are disposed alternately with each other in a direction perpendicular to a thickness direction of the window.

3. The display apparatus of claim 1, wherein the first portion has a relatively negative charge and the second portion has a relatively positive charge.

4. The display apparatus of claim 3, wherein the first refractive index is less than the second refractive index.

5. The display apparatus of claim 1, wherein a thickness of the first portion in a thickness direction of the window is less than a thickness of the window.

6. The display apparatus of claim 1, wherein the first portion and the second portion are disposed on an upper surface of the window.

7. An electronic device comprising:
a display apparatus comprising:
a display panel comprising a plurality of light-emitting diodes disposed on a substrate; and
a window disposed on the display panel and covering the display panel,
wherein the window comprises, on an upper surface of the window, a first zone having a first refractive index and a second zone having a second refractive index different from the first refractive index, wherein the first zone and the second zone are disposed alternately with each other in a direction perpendicular to a thickness direction of the window.

8. The electronic device of claim 7, wherein the first refractive index of the first zone is less than the second refractive index of the second zone.

9. The electronic device of claim 7, wherein the first zone has a relatively negative charge as compared to the second zone.

10. The electronic device of claim 7, wherein the upper surface of the window has undergone thermal poling treatment.

11. The electronic device of claim 10, wherein the thermal poling treatment comprises treatment of bringing an electrode into contact with the first zone of the upper surface of the window and applying a voltage to the electrode.

12. The electronic device of claim 7, wherein a lower surface of the window facing the display panel has a constant refractive index in the direction perpendicular to the thickness direction of the window.

13. A method of manufacturing a display apparatus, the method comprising:
bringing an electrode having a protrusion into contact with a first surface of a window;
performing thermal poling treatment on the window by applying a voltage to the window through the electrode; and
attaching the window on which the thermal poling treatment has been performed onto a display panel comprising a plurality of light-emitting diodes.

14. The method of claim 13, further comprising disposing the window between an anode and a cathode.

15. The method of claim 14, wherein the electrode is disposed between the first surface of the window and the anode.

16. The method of claim 14, wherein the cathode is in direct contact with a second surface of the window, the second surface being opposite to the first surface of the window.

17. The method of claim 13, wherein the protrusion of the electrode is in contact with a first zone of the first surface of the window.

18. The method of claim 17, wherein the performing of the thermal poling treatment comprises moving a positive charge positioned in the first zone to a second zone adjacent to the first zone by applying a positive voltage to the first zone.

19. The method of claim 13, wherein the performing of the thermal poling treatment is at a temperature of 200° C. or more.

20. The method of claim 13, wherein, in the attaching of the window onto the display panel, the first surface of the window faces in a direction away from the display panel.
